(19) United States
(12) Patent Application Publication
(10) Pub. No.: US 2026/0105225 A1
(43) Pub. Date: Apr. 16, 2026

(54) MINING PLANNING METHOD, SYSTEM, STORAGE MEDIUM, AND DEVICE

(71) Applicant: CHINA UNIVERSITY OF PETROLEUM-BEIJING, Beijing (CN)

(72) Inventors: Yingying WANG, Beijing (CN); Zhuo CHENG, Beijing (CN); Ke WANG, Beijing (CN); Bolin LIU, Beijing (CN); Chuanbo CONG, Beijing (CN); Haibo SUN, Beijing (CN); Yufang LI, Beijing (CN)

(21) Appl. No.: 19/291,380

(22) Filed: Aug. 5, 2025

(30) Foreign Application Priority Data
Oct. 11, 2024 (CN) 202411419477.3

(51) Int. Cl. G06F 30/28

(52) U.S. Cl. CPC G06F 30/28

(57) ABSTRACT

A mining planning method is provided. The method includes: acquiring physical characteristics and initial parameters of an ore particle group; performing numerical simulation on the ore particle group based on the physical characteristics and the initial parameters to calculate resistance coefficient values of the ore particle group corresponding to different flow velocity values; establishing a mathematical relationship between a resistance coefficient and a flow velocity; calculating a settling velocity of the ore particle group based on the mathematical relationship; and calculating a minimum lifting velocity of the ore particle group based on the settling velocity, where the minimum lifting velocity is for guiding mining planning. The resistance coefficient and the settling velocity of the particle group are calculated accurately through the numerical simulation, and thus the minimum lifting velocity is determined. A mining planning system, a computer-readable storage medium, and an electronic device are further provided.

### CROSS-REFERENCE TO RELATED APPLICATIONS

The present application claims priority to Chinese Patent Application No.202411419477.3, titled “MINING PLANNING METHOD, SYSTEM, STORAGE MEDIUM, AND DEVICE”, filed on Oct. 11, 2024 with the China National Intellectual Property Administration, which is incorporated herein by reference in its entirety.

### FIELD

The present disclosure relates to the field of deep-sea mining, and in particular to a mining planning method and system, a storage medium, and a device.

### BACKGROUND

Deep-sea mining involves a process of transporting ores from seabed to sea surface via a hydraulic lifting system. To ensure that ore particles are lifted smoothly, it is required to determine a minimum lifting velocity. In conventional methods, typically attention is paid to a resistance coefficient and a settling velocity of an individual particle, but these methods may be inaccurate during dealing with a particle group. Therefore, how to more accurately determine a lifting velocity is a technical issue to be addressed for those skilled in the art.

### SUMMARY

An objective of the present disclosure is to provide a mining planning method and system, a computer-readable storage medium, and an electronic device. A resistance coefficient of a particle group is calculated through numerical simulation, and a settling velocity of the ore particle group is combined, so as to calculate a minimum lifting velocity, thereby providing a reliable basis for setting hydraulic lifting parameters during a deep-sea mining process.

To address the above-described technical issues, a mining planning method is provided according to the present disclosure, and technical solutions is described as follows:
acquiring physical characteristics and initial parameters of an ore particle group;
performing numerical simulation on the ore particle group based on the physical characteristics and the initial parameters to calculate resistance coefficient values of the ore particle group corresponding to different flow velocity values, and establishing a mathematical relationship between a resistance coefficient and a flow velocity;
calculating a settling velocity of the ore particle group based on the mathematical relationship; and
calculating a minimum lifting velocity of the ore particle group based on the settling velocity, where the minimum lifting velocity is used to guide mining planning.

In an embodiment, the performing numerical simulation on the ore particle group based on the physical characteristics and the initial parameters includes:
constructing an initial geometric model of the ore particle group based on the physical characteristics and the initial parameters, where the initial geometric model includes ore particles of different sizes and shapes; and
establishing a coupling model of a fluid domain and a solid domain based on the initial geometric model.

In an embodiment, the establishing a coupling model of a fluid domain and a solid domain based on the initial geometric model includes:
describing fluid domain motion of the ore particles by using Navier-Stokes equation;
describing solid domain motion of the ore particles by using Newton's second law;
and

establishing the coupling model based on the fluid domain motion and the solid domain motion.

In an embodiment, the establishing the coupling model based on the fluid domain motion and the solid domain motion includes:
defining a Lagrangian point and an Eulerian grid; and
coupling the Lagrangian point and the Eulerian grid through an interpolation function, where the interpolation function is for translating a force on a solid boundary into a force on a fluid grid point, and for transferring a reaction force of a fluid on the solid boundary from the fluid grid point to the Lagrangian point.

In an embodiment, the coupling the Lagrangian point and the Eulerian grid through an interpolation function includes:
step A, initializing physical parameters and initial positions of the fluid domain and a solid particle, and constructing an Eulerian grid for the fluid domain and a Lagrangian point for the solid boundary;
step B, solving a velocity field and a pressure field of the fluid domain by using Navier-Stokes equation;
step C, calculating the force on the solid boundary, applying the force to the fluid domain, and updating a position and a velocity of the Lagrangian point;
step D, transferring the force on the solid boundary to the fluid grid point through the interpolation function and calculating a reaction force of the fluid on the solid boundary;
step E, updating the velocity field of the fluid domain and a position and a velocity of the solid particle by using a flow field in the fluid domain and a motion equation of the solid domain; and
iterating steps A to E to perform iteration calculations in time steps, and stopping the iterative calculations in response to an iteration duration reaching a predefined simulation duration or a convergence condition being satisfied.

In an embodiment, the calculating a settling velocity of the ore particle group based on the mathematical relationship includes:
establishing a force model of an ore particle, where the force model includes interactions of gravity, buoyancy, and fluid resistance;
calculating the settling velocity of the ore particle based on the gravity, the buoyancy, and the fluid resistance; and
determining the settling velocity of the ore particle group based on an overall resistance coefficient and an average diameter of the ore particle group.

In an embodiment, the calculating a minimum lifting velocity of the ore particle group based on the settling velocity includes:
calculating the minimum lifting velocity of the ore particle group based on the settling velocity and design parameters of a hydraulic lifting system.

A mining planning system is further provided according to the present disclosure, and the system includes a data acquisition module, a numerical simulation module, a settling velocity calculation module and a mining planning module.

The data acquisition module is configured to acquire physical characteristics and initial parameters of an ore particle group.

The numerical simulation module is configured to perform numerical simulation on the ore particle group based on the physical characteristics and the initial parameters to calculate resistance coefficient values of the ore particle group corresponding to different flow velocity values, and establish a mathematical relationship between a resistance coefficient and a flow velocity.

The settling velocity calculation module is configured to calculate a settling velocity of the ore particle group based on the mathematical relationship.

The mining planning module is configured to calculate a minimum lifting velocity of the particle group based on the settling velocity, where the minimum lifting velocity is for guiding mining planning.

A non-transitory computer readable storage medium is further provided according to the present disclosure. The computer readable storage medium stores a computer program that, when being executed, is to implement the steps of the mining planning method described above.

An electronic device is further provided according to the present disclosure. The electronic device includes a memory and a processor. The memory is configured to store a computer program, and the processor is configured to invoke the computer program in the memory to perform the steps of the mining planning method described above.

According to the present disclosure, a mining planning method is provided, and the method includes: acquiring physical characteristics and initial parameters of an ore particle group; performing numerical simulation on the ore particle group based on the physical characteristics and the initial parameters to calculate resistance coefficient values of the ore particle group corresponding to different flow velocity values; establishing a mathematical relationship between a resistance coefficient and a flow velocity; calculating a settling velocity of the ore particle group based on the mathematical relationship; and calculating a minimum lifting velocity of the ore particle group based on the settling velocity, where the minimum lifting velocity is used to guide mining planning.

According to the present disclosure, the resistance coefficient and the settling velocity of the particle group is calculated accurately through the numerical simulation, and thus the minimum lifting velocity is determined, which ensures smooth lifting of the ore particles, and provides an important reference basis for design and optimization of the hydraulic lifting system for deep-sea mining.

A mining planning system, a computer-readable storage medium, and an electronic device according to the present disclosure have the above-described beneficial effects, which are not repeated here.

### BRIEF DESCRIPTION OF THE DRAWINGS

For more clearly illustrating embodiments of the present disclosure or the technical solutions in the conventional technology, drawings referred to describe the embodiments or the conventional technology will be briefly described hereinafter. Apparently, the drawings in the following description are only some embodiments of the present disclosure, and for those skilled in the art, other drawings may be obtained based on these drawings without any creative efforts.

FIG. 1 is a flowchart of a mining planning method according to an embodiment of the present disclosure;

FIG. 2 is a flowchart of performing numerical simulation by using an immersed boundary method according to an embodiment of the present disclosure;

FIG. 3 is a schematic diagram of an initial geometric model of an ore particle group according to an embodiment of the present disclosure;

FIG. 4 is a flowchart of a mining planning method according to another embodiment of the present disclosure;

FIG. 5 is a schematic structural diagram of a mining planning system according to an embodiment of the present disclosure; and

FIG. 6 is a structural diagram of an electronic device according to an embodiment of the present disclosure.

### DETAILED DESCRIPTION

In order to make the objectives, technical solutions and advantages of the embodiments of the present disclosure clearer, the technical solutions in the embodiments of the present disclosure will be described clearly and completely hereinafter with reference to the drawings in the embodiments of the present disclosure. Apparently, the described embodiments are a part of embodiments of the present disclosure, rather than all of embodiments. Based on the embodiments of the present disclosure, all other embodiments obtained by those skilled in the art without any creative work fall into the protection scope of the present disclosure.

The object information (including but not limited to object device information and object personal information) and data (including but not limited to to-be-analyzed data, stored data, and displayed data) involved in the present disclosure are all authorized by an object or fully authorized by all parties. In addition, the collection, usage and processing of the relevant data comply with laws, regulations, and standards of relevant countries and regions.

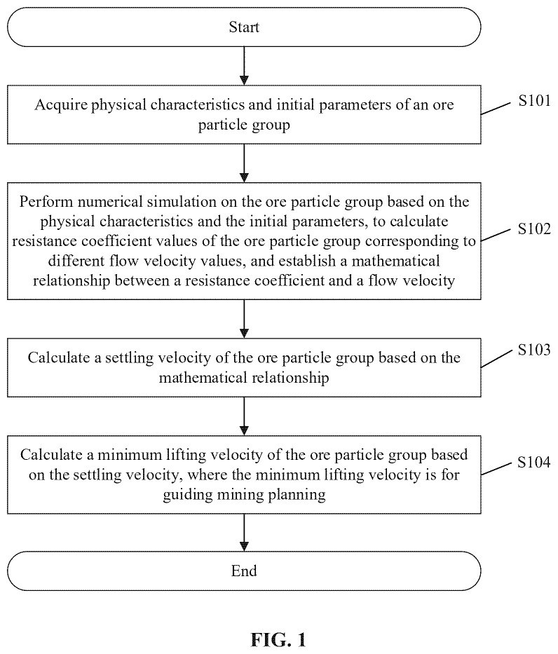

Reference is made to FIG. 1, which is a flowchart of a mining planning method according to an embodiment of the present disclosure. The method includes the following step S101 to step S104.

In step S101, physical characteristics and initial parameters of an ore particle group are acquired.

In step S102, numerical simulation is performed on the ore particle group based on the physical characteristics and the initial parameters to calculate resistance coefficient values of the ore particle group corresponding to different flow velocity values, and a mathematical relationship between a resistance coefficient and a flow velocity is established.

In step S103, a settling velocity of the ore particle group is calculated based on the mathematical relationship.

In step S104, a minimum lifting velocity of the particle group is calculated based on the settling velocity, where the minimum lifting velocity is for guiding mining planning.

First, the physical characteristics and the initial parameters of the ore particle group are determined. The physical characteristics of the ore particle group include density, shape, size, and initial distribution of particles. These parameters are for constructing an initial geometric model of the particle group.

Direct numerical simulation is performed on the particle group by using an immersed boundary method. A numerical simulation process by using the immersed boundary method includes the following two steps.

In a first step, an initial geometric model of the particle group is constructed.

The model includes multiple ore particles of different sizes and shapes, accurately reflecting actual situations.

In a second step, a coupling model of a fluid domain and a solid domain is established.

In this step, coupling calculation of the fluid domain and the solid domain is performed. In a calculation process by using the immersed boundary method, the coupling calculation of the fluid domain and the solid domain is a critical part. The process involves transferring a force on a boundary of a solid particle to the fluid domain, and the resulting a reaction force of the fluid domain in turn affect the motion of the solid particle. A detailed description and equations are shown below.

Motion in the fluid domain is described by using Navier-Stokes equation, which include a momentum equation and a continuity equation.

The momentum equation is expressed as follows:

$$\frac{\partial u}{\partial t} + ( u \cdot ∇ ) u = - \frac{1}{ρ} ∇ p + v {∇}^{2} u + f ;$$

where d represents a particle diameter (m), and φ represents a particle shape factor, u represents a fluid velocity vector (m/s), t represents time(s), ρ represents a fluid density (kg/m³), P represents pressure (Pa), v represents fluid dynamic viscosity (m²/s), and f represents a body force (N/m³).

The continuity equation (mass conservation) is expressed as follows:

$$∇ \cdot u = 0.$$

In a solid domain equation, the motion of a solid particle is described through Newton's second law as follows, which considers the balance of forces:

$${m}_{s} \frac{{d}^{2} {X}_{s}}{{dt}^{2}} = {F}_{s} + {F}_{b} ;$$

where mₛ represents a particle mass (kg), Xₛ represents a position vector of the solid particle, Fₛ represents a force (N) exerted by the fluid on the solid particle and F_{b} represents an interaction force (N) between solid particles.

In the immersed boundary method, coupling between the fluid domain and the solid domain is implemented through interaction between a Lagrangian point and an Eulerian grid. The specific process is expressed as follows.

First, a Lagrangian point and an Eulerian grid are defined: the Lagrangian point is for describing a solid boundary, and the Eulerian grid is for describing the fluid domain. The Lagrangian point and the Eulerian grid are coupled through an interpolation function. In the following, Xₛ represents coordinates of the Lagrangian point on the solid boundary, and Xᵢ represents coordinates of a fluid grid point.

Then, the interpolation function is defined. To achieve the interaction between the Lagrange point and the Eulerian grid, the interpolation function is expressed as follows:

$$δ ( x ) = \frac{1}{Δ x \sqrt{π}} exp ( - \frac{{x}^{2}}{Δ {x}^{2}} ) ;$$

Through the interpolation function, a force Fₛ on the solid boundary is applied to the fluid domain and is translated into a force fᵢ on the fluid grid point, which is expressed as follows:

$${f}_{i} = {\sum }_{s} {F}_{s} δ ( {X}_{i} - {X}_{s} ) ;$$

Similarly, through the interpolation function, a reaction force of the fluid on the solid boundary is transferred from the fluid grid point to the Lagrangian point, the reaction force on the Lagrangian point is expressed as follows:

$${F}_{s} = {\sum }_{i} {f}_{i} δ ( {X}_{i} - {X}_{s} ) ;$$

Subsequently, coupling calculation is performed. Coupling the Lagrangian point and the Eulerian grid through the interpolation function includes the following step A to step E.

In step A, physical parameters and initial positions of the fluid domain and a solid particle are initialized, and an Eulerian grid for the fluid domain and a Lagrangian point for the solid boundary are constructed.

In step B, a velocity field and a pressure field of the fluid domain are solved by using Navier-Stokes equation.

In step C, the force on the solid boundary is calculated, the force is applied to the fluid domain, and a position and a velocity of the Lagrangian point are updated.

In step D, the force on the solid boundary is transferred to the fluid grid point through the interpolation function and a reaction force of the fluid on the solid boundary is calculated.

In step E, the velocity field of the fluid domain and a position and a velocity of the solid particle are updated by using a flow field in the fluid domain and a motion equation of the solid domain.

Steps A to E are iterated to perform iteration calculations in time steps, and the iterative calculations are stopped in response to an iteration duration reaching a predefined simulation duration or a convergence condition being satisfied.

In step A, the physical parameters and the initial positions of the fluid domain and a solid particle are initialized. An Eulerian grid for the fluid domain and a Lagrangian point for the solid boundary are constructed.

In step B, the velocity field and the pressure field of the fluid domain are solved by using Navier-Stokes equation.

In step C, the force Fₛ on the solid boundary is calculated and applied to the fluid domain. The position and the velocity of the Lagrangian point are then updated.

In step D, the force on the solid boundary is transferred to the fluid grid point through the interpolation function and a reaction force of the fluid on the solid boundary is calculated.

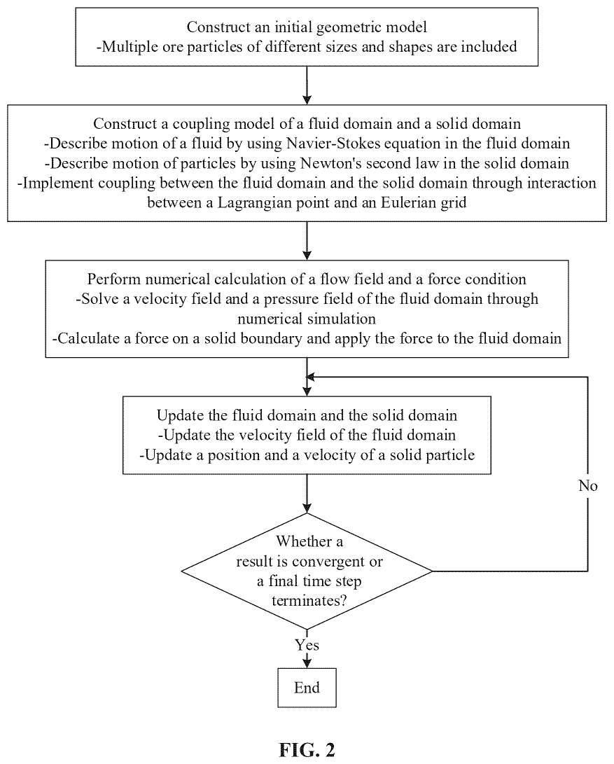

Reference is made to FIG. 2, which is a flowchart of performing numerical simulation by using an immersed boundary method according to an embodiment of the present disclosure. FIG. 2 illustrates a complete process of performing numerical simulation by using the immersed boundary method, which includes the following steps.

First, an initial geometric model is constructed. The initial geometric model of an ore particle group includes multiple ore particles of different sizes and shapes.

Second, a coupling model of a fluid domain and a solid domain is established. In the fluid domain, motion of the fluid is described by using Navier-Stokes equation. In the solid domain, motion of particles is described by using Newton's second law. Coupling between the fluid domain and the solid domain is implemented through interaction between a Lagrangian point and an Eulerian grid.

Then, numerical calculation of a flow field and a force condition is performed. A velocity field and a pressure field of the fluid domain are solved through numerical simulation. A force on a solid boundary is calculated and applied to the fluid domain.

When the fluid domain and the solid domain are updated, the velocity field of the fluid domain and a position and a velocity of a solid particle are updated.

The calculations are iterated until a result is convergent or a final time step terminates.

The above-described steps are repeated for performing iterative calculations in time steps, and the iterative calculations are not stopped until the calculation at the final time step is performed or a convergence condition is satisfied, that is, the iterative calculation are performed in time steps until a predefined simulation duration expires or a convergence condition is satisfied.

An example calculation process is described as follows.

Assuming that initial conditions of a solid particle are as follows:

$$particle density {ρ}_{s} = 2500 kg / {m}^{3} ;$$

$$particle diameter d = 0.01 m ;$$

$$fluid density {ρ}_{f} = 1000 kg / {m}^{3} ; and$$

$$dynamic viscosity v = 1 \times 1 {0}^{- 6} {m}^{2} / s ;$$

Parameters of the fluid domain and the solid particle are initialized, to construct an Eulerian grid and a Lagrangian point.

An initial fluid velocity field is calculated as:

$$u ( t = 0 ) = 0 ;$$

An initial force on the solid boundary is calculated as:

$${F}_{s} ( t = 0 ) = {F}_{g} - {F}_{b} = ( \frac{π}{6} {d}^{3} {ρ}_{s} g ) - ( \frac{π}{6} {d}^{3} {ρ}_{f} g ) ;$$

The force is applied to the fluid and the fluid velocity field is updated, where the force on the fluid grid point is expressed as:

$${f}_{i} ( t = 0 ) = {\sum }_{s} {F}_{s} δ ( {x}_{i} - {X}_{s} ) ;$$

A reaction force of the fluid on the solid boundary is calculated as:

$${F}_{s} ( t + Δ t ) = {\sum }_{i} {f}_{i} δ ( {x}_{i} - {X}_{s} ) ;$$

By iterating the above-described steps, a coupling calculation of a fluid domain and a solid domain is implemented until a convergence condition is satisfied or a predefined simulation duration expires.

$$u ( t + Δ t ) = u ( t ) + Δ t [ - ( u \cdot ∇ ) u + v {∇}^{2} u + f ] ;$$

$${X}_{s} ( t + Δ t ) = {X}_{s} ( t ) + {V}_{s} Δ t ;$$

After numerical simulation on an ore particle group is implemented, a resistance coefficient of the particle group is calculated. A manner of calculating the resistance coefficient is not limited here, and a feasible equation for calculating the resistance coefficient is expressed as follows:

$$Cd = Fd / ( 0.5 * ρ * {u}^{2} * A ) ;$$

where Cd represents the resistance coefficient, Fd represents a resistance (N) experienced by the particle group, ρ represents a fluid density (kg/m³), u represents a fluid velocity (m/s), A represents a windward area (m²) of the particle group, and Vs represents a particle velocity.

By calculating resistance coefficient values corresponding to different fluid velocity values through numerical simulation, a mathematical relationship between a resistance coefficient and a fluid velocity is determined. For example, a graph showing a variation of the resistance coefficient with the fluid velocity is plotted to facilitate calculating a settling velocity of the particle group subsequently.

Calculating the settling velocity of the particle group is one of critical steps in determining the minimum lifting velocity. The settling velocity reflects a motion velocity of the particle group after force balance in a static fluid or flowing fluid. A process of calculating the settling velocity is described as follows, and relevant equations and a physical model are listed. The process may include the following steps.

In a first step, a force model of an ore particle is established, where the force model includes interactions of gravity, buoyancy, and fluid resistance.

In a second step, the settling velocity of the ore particle is calculated based on the gravity, the buoyancy, and the fluid resistance.

In a third step, the settling velocity of the ore particle group is determined based on an overall resistance coefficient and an average diameter of the ore particle group.

In the fluid, the particle group is affected by the gravity, the buoyancy, and the fluid resistance. For a single particle, a force balance equation is expressed as:

$${F}_{g} - {F}_{b} - {F}_{d} = 0 ;$$

where F_{g} represents the gravity, F_{b} represents the buoyancy, and F_{d} represents the fluid resistance.

For the particle group, the force balance may be expanded to a sum of forces of all particles:

$$\sum ( {F}_{g} - {F}_{b} - {F}_{d} ) = 0 ;$$

For the gravity and the buoyancy in the above equation, gravity F_{g} and buoyancy F_{b} of a single particle are expressed as

$${F}_{g} = {m}_{s} \cdot g = \frac{π}{6} {d}^{3} {ρ}_{s} g ;$$

$${F}_{b} = {m}_{f} \cdot g = \frac{π}{6} {d}^{3} {ρ}_{f} g ;$$

where mₛ represents a particle mass, m_{f} represents a fluid displacement mass, d represents a particle diameter, ρₛ represents a particle density, ρ_{f} represents a fluid density, and g represents a gravitational acceleration.

The fluid resistance F_{d} is typically related to a velocity of the fluid and a shape of a particle, and is expressed by using the resistance coefficient C_{d}:

$${F}_{d} = \frac{1}{2} {C}_{d} {ρ}_{f} {Au}^{2} ;$$

For a single spherical particle, a windward area A is expressed as

$$A = π \frac{{d}^{2}}{4} ;$$

The resistance coefficient C_{d} is obtained through numerical simulation, and thus for different flow velocity values, the resistance coefficient values of the particle group are obtained.

The settling velocity Vₜ of the particle group is a velocity under a force balance condition. Based on a balance among the gravity, the buoyancy, and the resistance, an equation for the settling velocity is derived:

$${F}_{g} - {F}_{b} = {F}_{d} ;$$

The aforementioned equations of these forces are substituted into the equation as follows:

$$\frac{π}{6} {d}^{3} {ρ}_{s} g - \frac{π}{6} {d}^{3} {ρ}_{f} g = \frac{1}{2} {C}_{d} {ρ}_{f} π \frac{{d}^{2}}{4} {V}_{t}^{2} ;$$

The equation is rearranged to obtain:

$$( {ρ}_{s} - {ρ}_{f} ) g = \frac{3}{4} {C}_{d} {ρ}_{f} {V}_{t}^{2} ;$$

The settling velocity equation is expressed as follows:

$${V}_{t} = \sqrt{\frac{4 ( {ρ}_{s} - {ρ}_{f} ) gd}{3 {C}_{d} {ρ}_{f}}}$$

For the particle group, interactions between particles and flow characteristics of the fluid are considered for determining the settling velocity. The settling velocity of the particle group is calculated based on the overall resistance coefficient C_{d} and the average diameter d̅ of the particle group as follows:

$${V}_{t} = \sqrt{\frac{4 ( {ρ}_{s} - {ρ}_{f} ) g \overline{d}}{3 {C}_{d} {ρ}_{f}}} .$$

In the above equation, d̅ represents the average diameter of the particle group, which is obtained through statistical analysis.

Through numerical simulation by using the immersed boundary method, the resistance coefficient values C_{d} of the particle group at different flow velocities are obtained, and combined with physical characteristics of the particle group, the settling velocity is calculated. The specific steps are described as follows.

In a first step, initial parameters of the particle group are determined. The initial parameters include a particle density ρₛ, an average diameter d̅, and a fluid density ρ_{f}.

In a second step, numerical simulation is performed to obtain a resistance coefficient. Through numerical simulation by using an immersed boundary method, resistance coefficient values C_{d} of the particle group at different flow velocities are obtained.

In a third step, a settling velocity is calculated. By using the above-described settling velocity equation, combined with the C_{d} obtained through numerical simulation, the settling velocity of the particle group is calculated.

To better described the above-described calculation process, the parameters of an ore particle group are assumed as follows:

$${ρ}_{s} = 2500 kg / {m}^{3} ;$$

$${ρ}_{f} = 1000 kg / {m}^{3} ;$$

$$\overline{d} = 0.01 m ; and$$

$${C}_{d} = 0.05 ,$$

which is obtained through numerical simulation,
these parameters are substituted into the settling velocity equation:

$${V}_{t} = \sqrt{\frac{4 ( 2500 - 10 \; 00 ) \cdot 9.81 \cdot 0.01}{3 \cdot 0.5 \cdot 1000}} ;$$

The result is obtained

$${V}_{t} \approx 0.9 m / s ;$$

Settling behaviors of the particle group under different conditions are determined to provide foundational data for calculating the minimum lifting velocity.

To calculate the minimum lifting velocity, a reason for setting three times the settling velocity as the minimum lifting velocity is analyzed first.

In a hydraulic lifting process for deep-sea mining, the minimum lifting velocity (Vₘᵢₙ) is a critical parameter that ensures ore particles to be successfully lifted from the deep-sea bottom to the sea surface. In actual engineering applications, the minimum lifting velocity is typically set to three times the settling velocity (Vₜ) of the particle group. This empirical equation is derived from a comprehensive consideration based on multiple factors, including fluid dynamics, interaction in the particle group, and a safety margin for actual operations.

In a lifting system, the flow state of the fluid significantly affects motion of the particles. Fluid flow within a lifting pipeline typically is in a turbulent state, that is, the velocity and the pressure of the fluid fluctuate greatly, which leads to unstable motion of the particles. The minimum lifting velocity is set to three times the settling velocity, which ensures that all particles can be stably lifted under a turbulent condition without settling due to a transient velocity fluctuation.

Particles in the particle group are not only affected by the gravity and the fluid resistance but also exhibit phenomena like mutual collision and agglomeration. These phenomena increase complexity of particle lifting. By increasing the minimum lifting velocity, adverse effects of particle interactions on overall lifting performance is reduced, and the particle group are lifted as a whole.

Additionally, in engineering practice, a certain safety margin is typically considered to address unforeseen factors and errors in actual operations. The minimum lifting velocity is set to three times the settling velocity, which provides a large safety margin, and ensures reliability and stability of the system under different operating conditions.

In multiple actual operations and experimental studies, it is shown that setting the minimum lifting velocity to three times the settling velocity improves efficiency and reliability of the lifting system effectively. This empirical equation is validated through long-term engineering practices and becomes an important reference for design and operation.

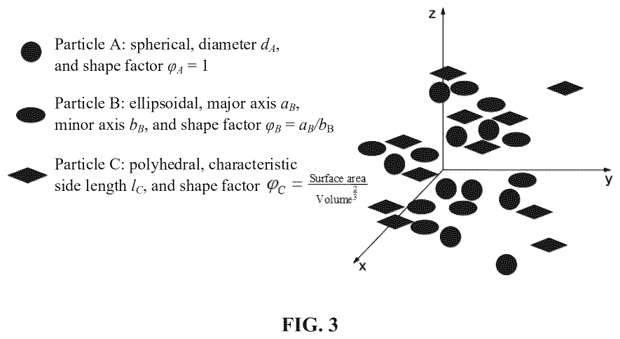

Reference is made to FIG. 3, which is a schematic diagram of an initial geometric model of an ore particle group according to an embodiment of the present disclosure. FIG. 3 illustrates a schematic diagram of an initial geometric model of the ore particle group, and shows distribution of particles of different sizes and shapes in a fluid. In FIG. 3, forces experienced by the ore particle group in the fluid and the settling and lifting processes of the ore particle group are shown.

FIG. 3 is a schematic diagram of an initial geometric model of an ore particle group. In the figure, particles of different sizes and shapes are illustrated, and the distribution of these particles in the fluid is described as follows.

A particle A is spherical, with a diameter d_{A}, and a shape factor φ_{A}=1.

A particle B is ellipsoidal, with a major axis a_{B}, a minor axis b_{B}, and a shape factor φ_{B}=a_{B}/b_{B}.

A particle C is polyhedral, with a characteristic side length l_{C} and a shape factor

$${φ}_{C} = \frac{Surface area}{{Volume}^{\frac{2}{3}}} .$$

As shown in FIG. 3, the particles are randomly distributed in the fluid. In view of the complexity of the particle group in actual situations, the particles are set in a random distribution manner. Spacings are set between particles to avoid collisions and interactions in an initial state.

FIG. 3 employs a three-dimensional coordinate system, where X, Y axes are set for representing horizontal directions, and Z axis is set for representing a vertical direction. An initial position of each particle is determined by coordinates (xᵢ, yᵢ, zᵢ) of a center point of the particle.

A fluid boundary condition is assumed to be a non-slipping boundary condition, that is, the velocity of a fluid at a particle surface is consistent with a particle velocity. An initial flow direction and velocity distribution are set in the fluid domain to simulate the motion of the particle group in the fluid.

A process of constructing the initial geometric model is described as follows.

First, particles of different sizes and shapes are generated by using a mathematical model. For a spherical particle, such as the particle A, a standard spherical model is used. For an ellipsoidal particle, such as the particle B, an ellipsoidal model defined by a major axis and a minor axis is used. For a polyhedral particle, such as the particle C, a polyhedral model defined by a characteristic side length and vertex coordinates is used.

The shape factor is used to describe an influence of a geometric shape of a particle on the motion behavior of the particle. The initial distribution of particles is generated by using a Monte Carlo method. By setting a parameter of a minimum spacing, it is ensured that an initial spacing between particles is sufficiently large to avoid collisions in the initial state.

For defining the fluid domain, the fluid domain is configured as a rectangular region, and a boundary condition and initial velocity distribution are set. The initial geometric model and the fluid domain parameters are imported through a numerical simulation software.

FIG. 3 shows an initial state of the ore particle group, which facilitates understanding of the forces and a motion behavior of the particle group in the fluid. By elaborating the shape, size, and distribution of the particles, numerical simulation and analysis can be performed more effectively, which improves computational accuracy and reliability.

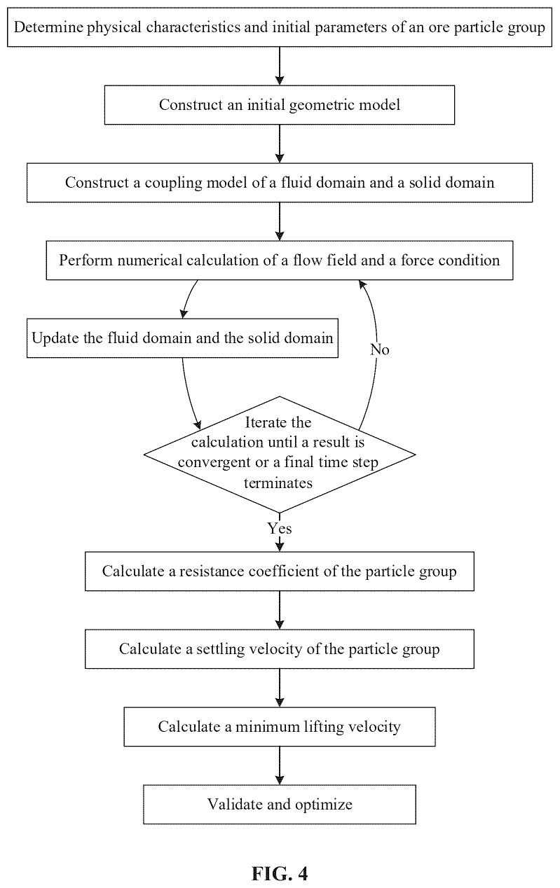

Reference is made to FIG. 4, which is a flowchart of a mining planning method according to another embodiment of the present disclosure. As shown in FIG. 4, the method includes the following steps.

Physical characteristics and initial parameters of an ore particle group are determined. Density, shape, size, and initial distribution of ore particles, as well as initial conditions and flow parameters of a fluid are determined.

An initial geometric model is constructed. A geometric model of the ore particle group is established, and the ore particle group includes particles of different sizes and shapes and is in the fluid domain.

A coupling model of a fluid domain and a solid domain is established. In the fluid domain, motion of the fluid is described by using Navier-Stokes equation. In the solid domain, motion of particles is described by using Newton's second law. Coupling between the fluid domain and the solid domain is implemented through interaction between a Lagrangian point and an Eulerian grid.

Numerical calculation of a flow field and a force condition is performed. A velocity field and a pressure field in the fluid domain are solved through numerical simulation. A force on a solid boundary is calculated and is applied to the fluid domain, and a position and a velocity of a particle is updated.

The fluid domain and the solid domain are updated. The velocity field of the fluid domain and a position and a velocity of a solid particle are updated based on a numerical calculation result.

The calculation is iterated until a result is convergent or a final time step terminates. The above-described steps are repeated. The iterative calculations are performed in time steps, until a predetermined simulation duration expires or a convergence condition is satisfied.

A resistance coefficient of the particle group is calculated. Based on the flow velocity and the force condition of the particles obtained from the numerical simulation, the resistance coefficient of the particle group (a ratio of the forces on the particle group in the fluid to the flow velocity) is calculated.

A settling velocity of the particle group is calculated. Based on the resistance coefficient of the particle group and fluid characteristics, the settling velocity of the particle group (the motion velocity of the particle group after force balance in a static fluid or flowing fluid) is calculated.

A minimum lifting velocity is calculated. The minimum lifting velocity is calculated based on the settling velocity of the particle group and design parameters of a hydraulic lifting system. Typically, the minimum lifting velocity is set to three times the settling velocity, to ensure that the particle group can be successfully lifted under complex deep-sea mining conditions.

The minimum lifting velocity is validated and optimized. Accuracy of a calculation result is validated through actual operations and experiments. Based on the validation result, design parameters of the lifting system are further optimized to ensure reliability and stability under different operation conditions.

Through these steps, dynamic characteristics of the ore particle group during a hydraulic lifting process are accurately simulated, and thereby the minimum lifting velocity is calculated. The minimum lifting velocity is for guiding mining planning and providing a reliable basis for hydraulic lifting parameter setting in a deep-sea mining process.

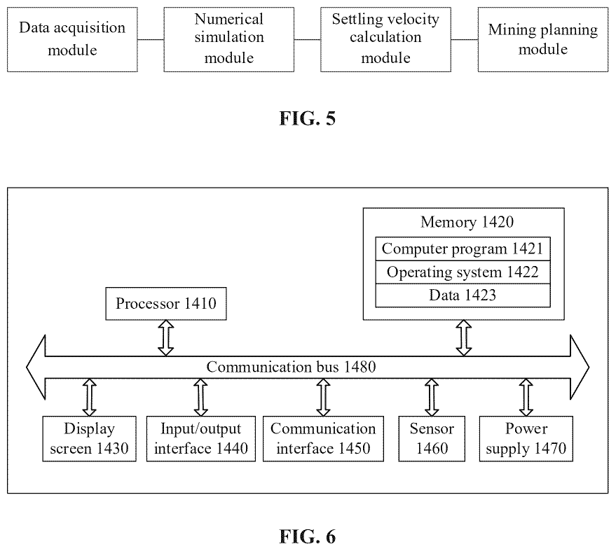

Reference is made to FIG. 5, which is a schematic structural diagram of a mining planning system according to an embodiment of the present disclosure. The mining planning system provided according to the present disclosure includes a data acquisition module, a numerical simulation module, a settling velocity calculation module and a mining planning module.

The data acquisition module is configured to acquire physical characteristics and initial parameters of an ore particle group.

The numerical simulation module is configured to perform numerical simulation on the ore particle group based on the physical characteristics and the initial parameters to calculate resistance coefficient values of the ore particle group corresponding to different flow velocity values, and establish a mathematical relationship between a resistance coefficient and a flow velocity.

The settling velocity calculation module is configured to calculate a settling velocity of the ore particle group based on the mathematical relationship.

The mining planning module is configured to calculate a minimum lifting velocity of the particle group based on the settling velocity, where the minimum lifting velocity is for guiding mining planning.

Based on the above-described embodiments, in a feasible embodiment, the numerical simulation module includes a first construction submodule and a second construction submodule.

The first construction submodule is configured to construct an initial geometric model of the ore particle group based on the physical characteristics and the initial parameters, where the initial geometric model includes ore particles of different sizes and shapes.

The second construction submodule is configured to establish a coupling model of a fluid domain and a solid domain based on the initial geometric model.

Based on the above-described embodiments, in a feasible embodiment, the second construction submodule includes a first description unit, a second description unit and a construction unit.

The first description unit is configured to describe fluid domain motion of the ore particles by using Navier-Stokes equation.

The second description unit is configured to describe solid domain motion of the ore particles by using Newton's second law.

The construction unit is configured to establish a coupling model based on the fluid domain motion and the solid domain motion.

Based on the above-described embodiments, in a feasible embodiment, the construction unit includes a defining subunit and a coupling subunit.

The defining subunit is configured to define a Lagrangian point and an Eulerian grid.

The coupling subunit is configured to couple the Lagrangian point and the Eulerian grid through an interpolation function, where the interpolation function is for translating a force on a solid boundary into a force on a fluid grid point, and for transferring a reaction force of a fluid on the solid boundary from the fluid grid point to the Lagrangian point.

Based on the above-described embodiment, in a feasible embodiment, the coupling subunit includes an execution subunit and an iteration subunit.

The execution subunit is configured to initialize physical parameters and initial positions of the fluid domain and a solid particle, and construct an Eulerian grid for the fluid domain and a Lagrangian point for the solid boundary; solve a velocity field and a pressure field of the fluid domain by using Navier-Stokes equation; calculate the force on the solid boundary, apply the force to the fluid domain, and update a position and a velocity of the Lagrangian point; transfer the force on the solid boundary to the fluid grid point through the interpolation function and calculate a reaction force of the fluid on the solid boundary; update the velocity field of the fluid domain and a position and a velocity of the solid particle by using a flow field in the fluid domain and a motion equation of the solid domain.

The iteration subunit is configured to iterate the calculation performed by the execution unit in time steps, and stop the iteration in response to an iteration duration reaching a predefined simulation duration or a convergence condition being satisfied.

Based on the above-described embodiments, in a feasible embodiment, the settling velocity calculation module includes a generation submodule, a first calculation submodule, and a determination submodule.

The generation submodule is configured to construct a force model of an ore particle, where the force model includes interactions of gravity, buoyancy, and fluid resistance.

The first calculation submodule is configured to calculate the settling velocity of the ore particle based on the gravity, the buoyancy, and the fluid resistance.

The determination submodule is configured to determine the settling velocity of the ore particle group based on an overall resistance coefficient and an average diameter of the ore particle group.

Based on the above embodiments, in a feasible embodiment, the mining planning module includes a second calculation submodule.

The second calculation submodule is configured to calculate the minimum lifting velocity of the ore particle group based on the settling velocity and design parameters of a hydraulic lifting system.

A computer-readable storage medium storing a computer program is further provided according to the present disclosure. The computer program, when executed, is to implement the steps provided in the above embodiments. The storage medium may include a USB disk, a mobile hard drive, a read-only memory (ROM), a random access memory (RAM), a magnetic disk or optical disk, and other media capable of storing program codes.

An electronic device is further provided according to the present disclosure. Reference is made to FIG. 6, which is a structural diagram of an electronic device according to an embodiment of the present disclosure. As shown in FIG. 6, the electronic device may include a processor 1410 and a memory 1420.

The processor 1410 includes one or more processing cores. For example, the processor 1410 is a 4-core processor, an 8-core processor, or the like. The processor 1410 may adopt at least one hardware form among the DSP (digital signal processing), the FPGA (field-programmable gate array), and the PLA (programmable logic array). The processor 1410 may further include a main processor and a coprocessor. The main processor is a processor for processing data in a wake-up state, also called a CPU (central processing unit). The coprocessor is a low-power processor for processing data in a standby state. In some embodiments, the processor 1410 may be integrated with a GPU (graphics processing unit), and the GPU is configured to render and draw content to be displayed on a display screen. In some embodiments, the processor 1410 may further include an AI (artificial intelligence) processor, and the AI processor is configured to process computing operations related to machine learning.

The memory 1420 may include one or more computer-readable storage media. The computer-readable storage medium may be non-transitory. The memory 1420 may further include a high-speed random access memory and a non-volatile memory, such as one or more magnetic disk storage devices and one or more flash memory storage devices. In the embodiment, the memory 1420 is at least configured to store a computer program 1421 as follows. The computer program after being loaded and executed by the processor 1410 can implement relevant steps in the method according to any forgoing embodiment, which are performed on an electronic device side. In addition, the memory 1420 may further store an operating system 1422, data 1423, and other resources in a temporary manner or a permanent manner. The operating system 1422 may include Windows, Linux, Android, and the like.

In some embodiments, the electronic device may further include a display 1430, an input/output interface 1440, a communication interface 1450, a sensor 1460, a power supply 1470 and a communication bus 1480.

The structure of the electronic device shown in FIG. 6 does not constitute a limitation on the electronic device according to the embodiment of the present disclosure. In practice, the electronic device may include more or fewer components than those shown in FIG. 6, or a combination of certain components.

The embodiments in the specification are described in a progressive manner. Each of the embodiments mainly focuses on differences from other embodiments, and references may be made to each other for the same or similar parts among the embodiments. Since the system disclosed in the embodiments corresponds to the method disclosed in the embodiments, the description of the system is relatively simple, and the relevant parts may be referred to the details in the method embodiments.

The principle and the embodiments of the present disclosure are described by specific examples. The above embodiments are described to facilitate understanding the method and the core idea of the present disclosure. It should be noted that, for those skilled in the art, several improvements and modifications may be made to the present disclosure without departing from the principle of the present disclosure, and these improvements and modifications also fall within the protection scope of the claims of the present disclosure.

It should be noted that in the specification, relationship terminologies such as “first” and “second” are only used to distinguish one entity or operation from another entity or operation, rather than to necessitate or imply an actual relationship or order between the entities or operations. Moreover, terms “include”, “comprise” or any variants thereof are intended to be non-exclusive. Therefore, a process, method, article or device including a series of elements includes not only the elements but also other elements that are not enumerated, or further includes elements inherent to the process, method, article or device. Unless expressively limited, the statement “including a . . . ” does not exclude the case that other identical elements may exist in the process, method, article or device including the series of elements.

1. A mining planning method, comprising:
acquiring physical characteristics and initial parameters of an ore particle group;
performing numerical simulation on the ore particle group based on the physical characteristics and the initial parameters, to calculate resistance coefficient values of the ore particle group corresponding to different flow velocity values;
establishing a mathematical relationship between a resistance coefficient and a flow velocity;
calculating a settling velocity of the ore particle group based on the mathematical relationship; and
calculating a minimum lifting velocity of the ore particle group based on the settling velocity, wherein the minimum lifting velocity is for guiding mining planning.

2. The mining planning method according to claim 1, wherein the performing numerical simulation on the ore particle group based on the physical characteristics and the initial parameters comprises:
constructing an initial geometric model of the ore particle group based on the physical characteristics and the initial parameters, wherein the initial geometric model comprises ore particles of different sizes and shapes; and
establishing a coupling model of a fluid domain and a solid domain based on the initial geometric model.

3. The mining planning method according to claim 2, wherein the establishing a coupling model of a fluid domain and a solid domain based on the initial geometric model comprises:
describing fluid domain motion of the ore particles by using Navier-Stokes equation;
describing solid domain motion of the ore particles by using Newton's second law; and
establishing the coupling model based on the fluid domain motion and the solid domain motion.

4. The mining planning method according to claim 3, wherein the establishing the coupling model based on the fluid domain motion and the solid domain motion comprises:
defining a Lagrangian point and an Eulerian grid; and
coupling the Lagrangian point and the Eulerian grid through an interpolation function, wherein the interpolation function is for translating a force on a solid boundary into a force on a fluid grid point, and for transferring a reaction force of a fluid on the solid boundary from the fluid grid point to the Lagrangian point.

5. The mining planning method according to claim 4, wherein the coupling the Lagrangian point and the Eulerian grid through an interpolation function comprises:
step A, initializing physical parameters and initial positions of the fluid domain and a solid particle, and constructing an Eulerian grid for the fluid domain and a Lagrangian point for the solid boundary;
step B, solving a velocity field and a pressure field of the fluid domain by using Navier-Stokes equation;
step C, calculating the force on the solid boundary, applying the force to the fluid domain, and updating a position and a velocity of the Lagrangian point;
step D, transferring the force on the solid boundary to the fluid grid point through the interpolation function and calculating the reaction force of the fluid on the solid boundary;
step E, updating the velocity field of the fluid domain and a position and a velocity of the solid particle by using a flow field in the fluid domain and a motion equation of the solid domain; and
iterating steps A to E to perform iteration calculations in time steps, and stopping the iterative calculations in response to an iteration duration reaching a predefined simulation duration or a convergence condition being satisfied.

6. The mining planning method according to claim 1, wherein the calculating a settling velocity of the ore particle group based on the mathematical relationship comprises:
establishing a force model of an ore particle, wherein the force model comprises interactions of gravity, buoyancy, and fluid resistance;
calculating the settling velocity of the ore particle based on the gravity, the buoyancy, and the fluid resistance; and
determining the settling velocity of the ore particle group based on an overall resistance coefficient and an average diameter of the ore particle group,
wherein the force model is expressed as
$${F}_{g} - {F}_{b} - {F}_{d} = 0 ,$$
wherein the F_{g} represents the gravity, F_{b} represents the buoyancy, and F_{d} represents the fluid resistance.

7. The mining planning method according to claim 1, wherein the calculating a minimum lifting velocity of the ore particle group based on the settling velocity comprises:
calculating the minimum lifting velocity of the ore particle group based on the settling velocity and design parameters of a hydraulic lifting system.

8. A mining planning system, comprising:
a data acquisition module, configured to acquire physical characteristics and initial parameters of an ore particle group;
a numerical simulation module, configured to perform numerical simulation on the ore particle group based on the physical characteristics and the initial parameters to calculate resistance coefficient values of the ore particle group corresponding to different flow velocity values, and establish mathematical relationship between a resistance coefficient and a flow velocity;
a settling velocity calculation module, configured to calculate a settling velocity of the ore particle group based on the mathematical relationship; and
a mining planning module, configured to calculate a minimum lifting velocity of the ore particle group based on the settling velocity, wherein the minimum lifting velocity is for guiding mining planning.

9. An electronic device, comprising:
a memory, configured to store a computer program; and
a processor, configured to perform the mining planning method according to claim 1 when executing the computer program.

10. A computer-readable storage medium storing a computer program, wherein the computer program, when executed, is to perform the mining planning method according to claim 1.
